(19) United States
(12) Patent Application Publication
(10) Pub. No.: US 2025/0391643 A1
(43) Pub. Date: Dec. 25, 2025

(54) APPARATUS FOR PROCESSING SUBSTRATE

(71) Applicant: ISAC RESEARCH INC., Daejeon (KR)

(72) Inventors: Hyung Sang PARK, Daejeon (KR); Seong Jun JEONG, Daejeon (KR); Ji Hye KIM, Daejeon (KR); Min Ho CHOI, Daejeon (KR)

(73) Assignee: ISAC RESEARCH INC., Daejeon (KR)

(21) Appl. No.: 19/208,031

(22) Filed: May 14, 2025

(30) Foreign Application Priority Data
Jun. 24, 2024 (KR) 10-2024-0081948

(51) Int. Cl. H01J 37/32; C23C 16/455; C23C 16/505

(52) U.S. Cl. CPC H01J 37/3244; C23C 16/45544; C23C 16/505; H01J 37/32357; H01J 37/32082; H01J 2237/332

(57) ABSTRACT

An apparatus for processing a substrate according to one aspect of the present disclosure includes: a chamber including a processing space in which the substrate is accommodatable and processible; a susceptor coupled to the chamber to support the substrate in the processing space; a gas supply device that is installed in the upper portion of the chamber and supplies a gas toward the susceptor; an RF power device configured to supply RF power to at least a portion of the gas supply device in order to form remote plasma in a reaction space in the gas supply device; and a bias power supply unit configured to selectively apply a bias voltage to another portion of the gas supply device or the susceptor.

### CROSS-REFERENCE TO RELATED APPLICATION

The present application claims priority under 35 U.S.C. § 119(a) to Korean Patent Application No. 10-2024-0081948, filed in the Korean Intellectual Property Office on Jun. 24, 2024, the entire contents of which application is incorporated herein by reference.

### STATEMENT REGARDING SPONSORED RESEARCH OR DEVELOPMENT

The research and development of the present disclosure were conducted with the support of the Korea Planning & Evaluation Institute of Industrial Technology (KEIT) with the financial resources of the Ministry of Trade, Industry and Energy (MOTIE) (Project Number: RS-2024-00406482, Detailed Project identifier: 2410000635).

### BACKGROUND OF THE INVENTION

### Field of the Invention

The present disclosure relates to semiconductor manufacturing, and more specifically, to an apparatus for processing a substrate.

### Description of Related Art

In order to manufacture semiconductor devices, various processes for processing a substrate are performed in a substrate processing apparatus under a vacuum atmosphere. For example, processes such as loading a substrate into a chamber and depositing a thin film on the substrate or etching the thin film can be performed. The substrate is supported on a susceptor installed in the chamber, and the substrate can be processed by injecting a process gas to the substrate through a gas supply device installed above the susceptor.

In such a substrate processing apparatus, when a thin film is deposited on the substrate, a gas can be activated using plasma. A gas activated using remote plasma formed outside the chamber can be supplied into the chamber. Using such remote plasma, it is required to increase a gas adsorption rate and increase a deposition rate when the thin film is formed.

### SUMMARY OF THE INVENTION

The present disclosure is intended to solve various problems including the above-mentioned problems, and an object thereof is to provide an apparatus for processing a substrate that can increase a gas adsorption rate and a deposition rate while using remote plasma. However, these problems are exemplary, and the scope of the present disclosure is not limited thereby.

An apparatus for processing a substrate according to one aspect of the present disclosure for solving the problems includes: a chamber including a processing space in which the substrate is accommodatable and processible; a susceptor coupled to the chamber to support the substrate in the processing space; a gas supply device that is installed in the upper portion of the chamber and supplies a gas toward the susceptor; an RF power device configured to supply RF power to at least a portion of the gas supply device in order to form remote plasma in a reaction space in the gas supply device; and a bias power supply unit configured to selectively apply a bias voltage to another portion of the gas supply device or the susceptor.

In the apparatus for processing a substrate, the gas supply device may include a top plate having a gas inlet formed therein, a first shower head that is disposed below the top plate and having first injection holes formed therein to inject a gas, and a first insulating side wall interposed between the shower head and the top plate to define the reaction space between the top plate and the shower head, the RF power device may be selectively connected to the top plate, and the first shower head may be grounded.

In the apparatus for processing a substrate, the bias power supply unit may be selectively connected to the susceptor.

In the apparatus for processing a substrate, a precursor may be supplied or a reaction gas may be supplied to the substrate through the gas supply device in order to form a thin film on the substrate using an atomic layer deposition (ALD) method, a bias voltage may be applied to the susceptor through the bias power supply unit when the precursor is supplied, and a bias voltage may not be applied to the susceptor and the susceptor may be grounded when the reaction gas is supplied.

In the apparatus for processing a substrate, the gas supply device may

further include a second shower head that is disposed below the first shower head and has second injection holes formed therein to inject a gas, and a second insulating side wall interposed between the first shower head and the second shower head to define a buffer space between the first shower head and the second shower head.

In the apparatus for processing a substrate, the bias power supply unit may be selectively connected to the second shower head.

In the substrate processing apparatus, the susceptor may be grounded.

In the apparatus for processing a substrate, a precursor may be supplied or a reaction gas may be supplied to the substrate through the gas supply device in order to form a thin film on the substrate using an atomic layer deposition (ALD) method, a bias voltage may be applied to the second shower head through the bias power supply unit when the precursor is supplied, and a bias voltage may not be applied to the second shower head when the reaction gas is supplied.

In the apparatus for processing a substrate, a bias voltage can be selectively applied to another portion of the gas supply device or the susceptor when the remote plasma is formed in the reaction space.

According to the apparatus for processing a substrate according to some embodiments of the present disclosure configured as described above, by generating the remote plasma and selectively applying a bias voltage, it is possible to increase a gas adhesion rate and increase a deposition rate when a thin film is formed. It is needless to say that the scope of the present disclosure is not limited by these effects.

### BRIEF DESCRIPTION OF THE DRAWINGS

FIG. 1 is a schematic cross-sectional view showing a substrate processing apparatus according to one embodiment of the present disclosure.

FIGS. 2 and 3 are schematic cross-sectional views showing operations of the substrate processing apparatus of FIG. 1.

FIG. 4 is a schematic cross-sectional view showing a substrate processing apparatus according to another embodiment of the present disclosure.

FIGS. 5 and 6 are schematic cross-sectional views showing operations of the substrate processing apparatus of FIG. 4.

### DETAILED DESCRIPTION OF THE INVENTION

Various preferred embodiments of the present disclosure will be described in detail below with reference to the accompanying drawings.

It should be understood that the embodiments of the present disclosure are provided to explain the present disclosure more completely to those having ordinary knowledge in the art, and the following embodiments may be modified in various different forms and the scope of the present disclosure is not limited to the following embodiments. Rather, these embodiments are provided to make the present disclosure more sufficient and complete and to completely convey the idea of the present disclosure to those skilled in the art. In addition, in the drawings, thicknesses or sizes of each layer are exaggerated for convenience and clarity of description.

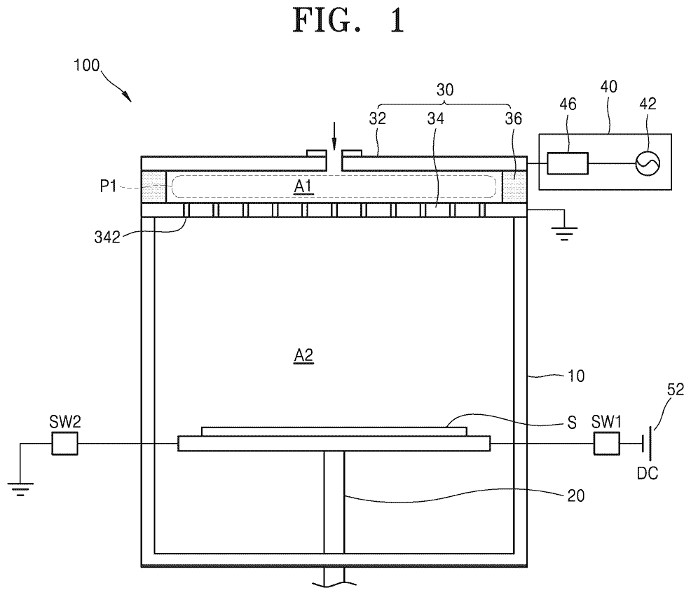

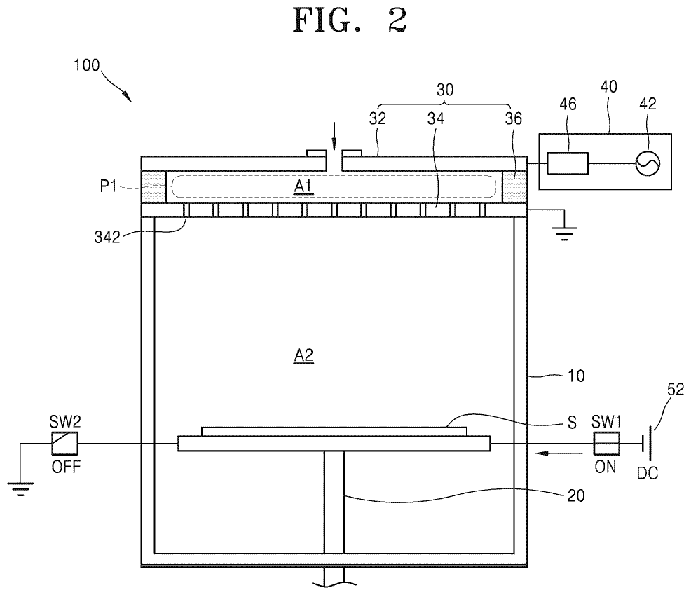

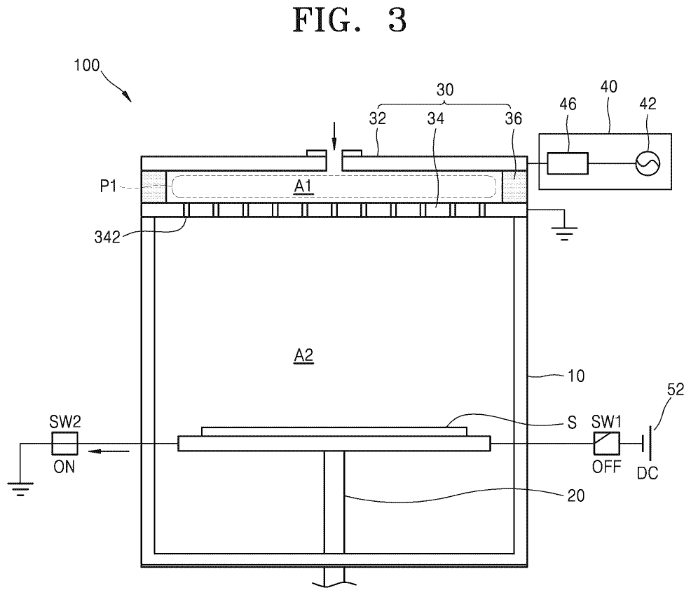

FIG. 1 is a schematic cross-sectional view showing a substrate processing apparatus 100 according to one embodiment of the present disclosure, and FIGS. 2 and 3 are schematic cross-sectional views showing operations of the substrate processing apparatus 100 of FIG. 1.

Referring to FIG. 1, the substrate processing apparatus 100 may include a chamber 10, a susceptor 20, a gas supply device 30, a radio frequency (RF) power device 40, and a bias power supply unit 52.

For example, the chamber 10 may have a structure provided with a processing space A2 in which at least one substrate S can be accommodated and processed. The chamber 10 may be connected to a vacuum pump (not shown) to form a vacuum atmosphere. Further, the chamber 10 may be provided with an entrance (not shown) for loading or unloading the substrate S into the processing space A2.

The chamber 10 may be provided in various shapes, and for example, may include a side wall portion that defines the processing space A2 and a cover portion that is located at an upper end of the side wall portion. This chamber 10 may be applied to various chambers of all types that have sufficient strength or durability to be able to support the susceptor 20 or the gas supply device 30 therein, and may be provided with various vacuum lines, pressure gauges, various sensors, or the like.

The susceptor 20 may be coupled to the chamber 10 to support the substrate S in the processing space A2. The susceptor 20 may be a kind of rotating turntable device that is installed in the processing space A2 and supports at least one substrate S. Accordingly, the substrate S can be rotated around a rotation axis by the susceptor 20. For example, the susceptor 20 may include a plate for supporting the substrate S and a shaft for supporting the plate from below.

The gas supply device 30 may be installed above the chamber 10 and may supply a gas toward the susceptor 20. For example, the gas supply device 30 may be a gas distribution device that is installed in the chamber 10 and can supply various process gases, for example, such as a source gas, a purge gas, and a reaction gas, in a time-division or space-division manner toward the substrate S.

For example, the gas supply device 30 may include a top plate 32, a first shower head 34, and a first insulating side wall 36. For example, the first shower head 34 may be disposed below the top plate 32 and coupled to the chamber 10 to inject the gas into the processing space A2. The top plate 32 may be disposed apart from the first shower head 34 and may have a gas inlet formed therein. First injection holes 342 for injecting a gas in a reaction space A1 into the processing space A2 are formed in the first shower head 34.

The first insulating side wall 36 may be interposed between the first shower head 34 and the top plate 32 to define the reaction space A1 between the top plate 32 and the first shower head 34. For example, the first insulating side wall 36 may be interposed between an end portion of the first shower head 34 and an end portion of the top plate 32. The insulating side wall 36 may have a function of providing electrical insulation between the top plate 32 and the first shower head 34 while defining the reaction space A1 between the top plate 32 and the first shower head 34.

In some embodiments, the gas supply device 30 may be insulated from the chamber 10. For example, if the chamber 10 is made of an insulating material, the first shower head 34 may be directly coupled to the chamber 10. In another example, if the chamber 10 is made of a conductive material, an insulating member (not shown) may be added between the chamber 10 and the first shower head 34. For example, an insulating O-ring may be inserted between the chamber 10 and the first shower head 34.

The RF power device 40 may supply RF power into the substrate processing apparatus 100. For example, the RF power device 40 may be coupled to a portion of the gas supply device 30 to supply the RF power to at least a portion of the gas supply device 30. For example, the RF power device 40 may supply high frequency (HF) power and/or low frequency (LF) power.

In some embodiments, the RF power device 40 may supply the RF power to at least a portion of the gas supply device 30 in order to form remote plasma P1 inside the gas supply device 30, that is, in the reaction space A1. Here, the plasma in the reaction space A1 may be called remote plasma in that the remote plasma P1 is formed in the substrate processing apparatus 100, but the reaction space A1 is separated from the processing space A2 in which the substrate S is disposed.

Since the remote plasma P1 is formed in the reaction space A1 in which there is no substrate S, supplying radicals generated using the remote plasma P1 onto the substrate S can reduce or eliminate plasma damage on the substrate S. Thus, the remote plasma P1 can be selectively formed as needed in the substrate processing apparatus 100.

In some embodiments, the RF power device 40 may include an RF power supply unit 42 that generates the RF power. The RF power supply unit 42 can supply high frequency (HF) power and/or low frequency (LF) power. The RF power device 40 may be selectively connected to the top plate 32, and thus the RF power supply unit 42 can be electrically connected to the top plate 32. Selectively, a switch capable of turning on or off transmission of the RF power may be interposed between the RF power supply unit 42 and the top plate 32. The first shower head 34 may be grounded, and thus the remote plasma P1 can be formed in the reaction space Al between the top plate 32 and the first shower head 34.

Additionally, an impedance matching unit 46 may be interposed between the RF power supply unit 42 and the top plate 32. The impedance matching unit 46 may perform impedance matching between the RF power supply unit 42 and the gas supply device 30.

In some embodiments, the bias power supply unit 52 may be provided to selectively apply a bias voltage to the susceptor 20 or another portion of the gas supply device 30. For example, the bias power supply unit 52 may be selectively connected to the susceptor 20 to apply a bias voltage to the susceptor 20. For example, when the remote plasma P1 is generated inside the reaction space A1 or a process is performed inside the processing space A2 without generating the remote plasma P1, the bias power supply unit 52 may selectively apply a bias voltage to the susceptor 20.

For example, the bias power supply unit 52 may supply a positive DC voltage, a negative DC voltage, or a pulsed voltage as a bias voltage. However, in modified examples of these embodiments, the bias power supply unit 52 may be modified to apply an AC bias voltage or an RF bias voltage in addition to a DC bias voltage.

In some embodiments, the bias power supply unit 52 may be connected to the susceptor 20 via a switch SW1, a bias voltage may be applied to the susceptor 20 when the switch SW1 is turned on, and a bias voltage may not be applied to the susceptor 20 when the switch SW1 is turned off.

Additionally, the susceptor 20 may be grounded via a switch SW2. For example, when the switch SW1 is turned off and a bias voltage is not applied to the susceptor 20, the switch SW2 may be turned on to ground the susceptor 20. On the other hand, in some embodiments, the switches SW1 and SW2 may be changed to a single multi-directional switch, and the susceptor 20 may be connected to the bias power supply unit 52 or grounded via the multi-directional switch.

In some embodiments, a guide rim may be installed on the substrate S mounted on the susceptor 20 in the substrate processing apparatus 100 to limit a section in which a bias voltage is applied.

Operations of the substrate processing apparatus 100 will be described in more detail below.

In some embodiments, as shown in FIG. 2, during at least some sections of a processing process for the substrate S, the switch SW1 may be turned on and the switch SW2 may be turned off to supply a bias voltage to the susceptor 20 from the bias power supply unit 52.

For example, in a case in which the RF power device 40 supplies the RF power to the top plate 32 and the first shower head 34 is grounded, the remote plasma P1 may be formed inside the reaction space A1. Further, during at least some sections of the processing process for the substrate S, when the remote plasma P1 is formed inside the reaction space A1, the switch SW1 may be turned on and the switch SW2 may be turned off to supply a bias voltage to the susceptor 20 from the bias power supply unit 52.

In another example, during at least some sections of the processing process for the substrate S, when the remote plasma P1 is not formed inside the reaction space A1 and a gas is supplied to the reaction space A1, a bias voltage may be supplied to the susceptor 20 from the bias power supply unit 52.

When a thin film is processed using the substrate processing apparatus 100, if a gas is injected into the reaction space Al and the remote plasma P1 is formed in the reaction space A1, the gas can be activated inside the reaction space Al. Subsequently, the activated gas, for example, radicals, can be supplied onto the substrate S inside the processing space A2 through the first shower head 34. In this case, if a bias voltage is applied to the susceptor 20, an adsorption rate of the gas including the radicals on the substrate S can be increased.

Accordingly, a thin film processing rate on the substrate S can be improved. For example, a thin film deposition rate on the substrate S can be increased during atomic layer deposition, and in another example, a thin film etching rate on the substrate S can be increased during atomic layer etching. Further, as the gas adsorption rate is improved, a material with a low adsorption factor, such as a 2D material, can also be used as the substrate S.

In some embodiments, as shown in FIG. 3, during at least some sections of a process for processing the substrate S, the switch SW1 may be turned off and the switch SW2 may be turned on to ground the susceptor 20.

For example, during at least some sections of the process for processing the substrate S, in a state in which the remote plasma P1 is formed in the reaction space A1, the switch SW1 may be turned off and the switch SW2 may be turned on to ground the susceptor 20.

In another example, during at least some sections of the process for processing the substrate S, in a state in which the remote plasma P1 is not formed in the reaction space A1, the switch SW1 may be turned off and the switch SW2 may be turned on to ground the susceptor 20.

In some embodiments, a process of depositing a thin film on the substrate S by atomic layer deposition (ALD) using the substrate processing apparatus 100 will be exemplarily described.

In order to form a thin film on the substrate S using the atomic layer deposition (ALD) method, a precursor or a reaction gas may be supplied to the substrate S through the gas supply device 30. For example, a cycle of supplying the precursor onto the substrate S to adsorb the precursor on the substrate S and then supplying a reaction gas onto the substrate S to form the thin film on the substrate S in atomic layer units may be repeated a plurality of times to form the thin film having a predetermined thickness on the substrate S. Further, a step of supplying a purge gas onto the substrate S before supplying the reaction gas after supplying the precursor in the cycle and a step of supplying a purge gas onto the substrate S after supplying the reaction gas may be added.

In some embodiments, during the above-described atomic layer deposition, a bias voltage may be applied to the susceptor 20 through the bias power supply unit 52 when a precursor or a source gas is supplied, and a bias voltage may not be applied to the susceptor 20 and the susceptor 20 may be grounded when a reaction gas is supplied. Accordingly, an adsorption rate of the precursor or source gas on the substrate S can be increased, thereby increasing the thin film deposition rate.

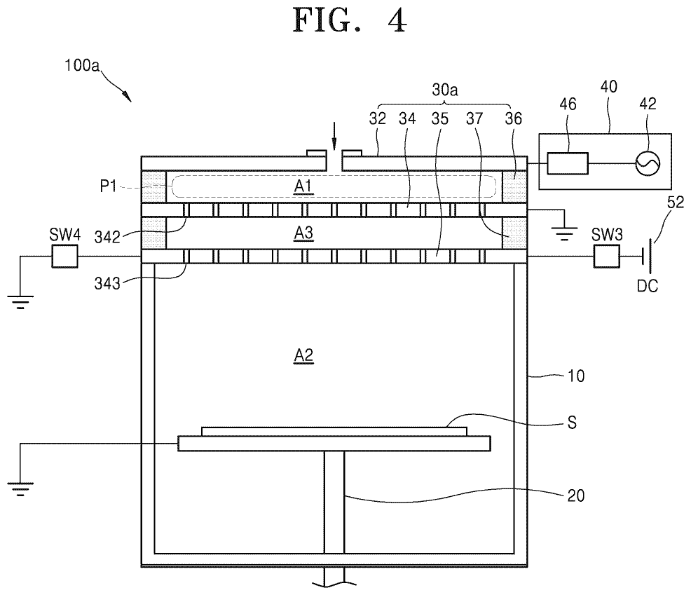

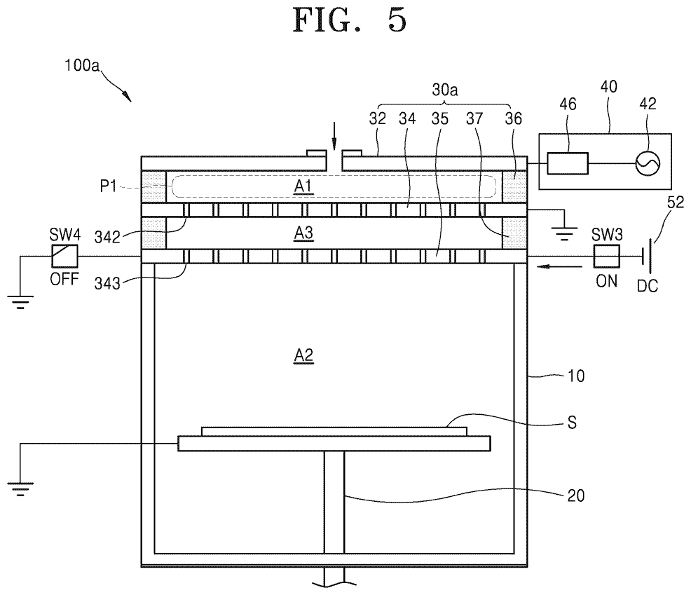

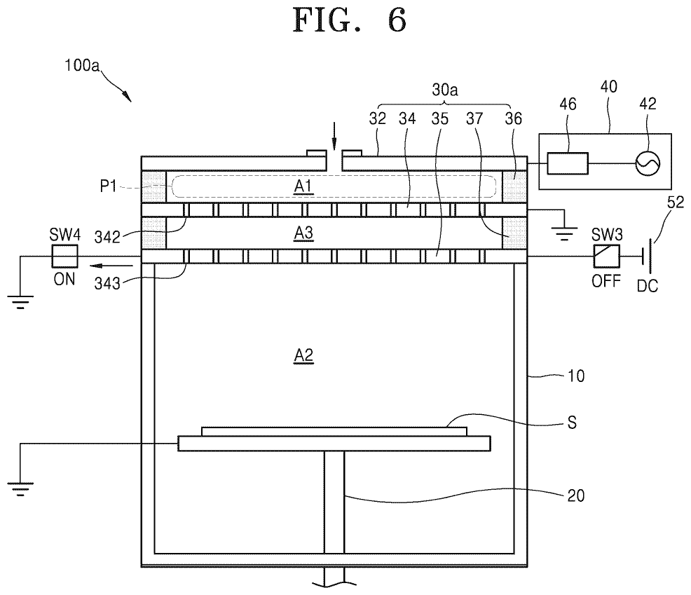

FIG. 4 is a schematic cross-sectional view showing a substrate processing apparatus 100a according to another embodiment of the present disclosure, and FIGS. 5 and 6 are schematic cross-sectional views showing operations of the substrate processing apparatus 100a of FIG. 4. The substrate processing apparatus 100a is a device obtained by adding some components to or changing some components of the substrate processing apparatus 100 of FIGS. 1 and 3, and they can be referenced from each other, and thus, repeated descriptions thereof in the embodiments will be omitted.

Referring to FIG. 4, the substrate processing apparatus 100a may include the chamber 10, the susceptor 20, a gas supply device 30a, the RF power device 40, and the bias power supply unit 52.

The gas supply device 30a may include the top plate 32, the first shower head 34, a second shower head 35, the first insulating side wall 36, and a second insulating side wall 37.

For example, a gas inlet may be formed in the top plate 32, the first shower head 34 may be disposed below the top plate 32, and the first injection holes 342 for injecting a gas may be formed in the first shower head 34. The first insulating side wall 36 may be interposed between the first shower head 34 and the top plate 32 to define the reaction space A1 between the top plate 32 and the first shower head 34.

The second shower head 35 may be disposed below the first shower head 34, and second injection holes 343 for injecting a gas may be formed in the second shower head 35. The second insulating side wall 37 may be interposed between the first shower head 34 and the second shower head 35 to define a buffer space A3 between the first shower head 34 and the second shower head 35. For example, the second insulating side wall 37 may be interposed between an end portion of the first shower head 34 and an end portion of the second shower head 35.

In the gas supply device 30a, gases may be introduced into the reaction space A1 through the gas inlet of the top plate 32, injected into the buffer space A3 through the first injection holes 342 of the first shower head 34, then injected into the processing space A2 through the second injection holes 343 of the second shower head 35, and thus supplied onto the substrate S.

In some embodiments, the gas supply device 30a may be insulated from the chamber 10. For example, if the chamber 10 is made of an insulating material, the second shower head 35 may be directly coupled to the chamber 10. In another example, if the chamber 10 is formed of a conductive material, an insulating member (not shown) may be added between the chamber 10 and the second shower head 35. For example, an insulating O-ring may be inserted between the chamber 10 and the second shower head 35.

The RF power device 40 may supply the RF power to at least a portion of the gas supply device 30 to form the remote plasma P1 inside the gas supply device 30a, that is, in the reaction space A1. The RF power device 40 may be selectively connected to the top plate 32, and thus the RF power supply unit 42 may be electrically connected to the top plate 32. The first shower head 34 may be grounded, and thus, the remote plasma P1 may be formed in the reaction space A1 between the top plate 32 and the first shower head 34.

The bias power supply unit 52 may be selectively connected to another portion of the gas supply device 30a, for example, to the second shower head 35. For example, the bias power supply unit 52 may selectively apply a bias voltage to the second shower head 35. For example, the bias power supply unit 52 may be connected to the second shower head 35 via a switch SW3, and when the switch SW3 is turned on, the bias voltage may be applied to the second shower head 35, and when the switch SW3 is turned off, the bias voltage may not be applied to the second shower head 35.

Additionally, the second shower head 35 may be grounded via a switch SW4. For example, when the switch SW3 is turned off and the bias voltage is not applied to the second shower head 35, the switch SW4 may be turned on to ground the second shower head 35. On the other hand, in some embodiments, the switches SW3 and SW4 may be changed to a single multi-directional switch, and the second shower head 35 may be connected to the bias power supply unit 52 or grounded via the multi-directional switch.

In some embodiments, the susceptor 20 may be grounded.

Operations of the substrate processing apparatus 100a will be described in more detail below.

In some embodiments, as shown in FIG. 5, during at least some sections of the processing process for the substrate S, the switch SW3 may be turned on and the switch SW4 may be turned off to supply a bias voltage to the second shower head 35 from the bias power supply unit 52.

For example, during at least some sections of the processing process for the substrate S, when the remote plasma P1 is formed inside the reaction space A1, the switch SW3 may be turned on and the switch SW4 may be turned off to supply a bias voltage to the second shower head 35 from the bias power supply unit 52.

In another example, during at least some sections of the processing process for the substrate S, when the remote plasma P1 is not formed inside the reaction space A1, a bias voltage may be supplied to the second shower head 35 from the bias power supply unit 52.

When a thin film is processed using the substrate processing apparatus 100a, if a gas is injected into the reaction space A1 and the remote plasma P1 is formed inside the reaction space A1, the gas may be activated inside the reaction space A1. Then, the activated gas, for example, radicals, may be supplied to the buffer space A3 through the first shower head 34, and then supplied onto the substrate S in the processing space A2 through the second shower head 35. In this case, if a bias voltage is applied to the second shower head 35, the adsorption rate of the gas including the radicals on the substrate S may be increased.

Accordingly, the thin film processing rate on the substrate S can be improved. For example, the thin film deposition rate on the substrate S can be improved during atomic layer deposition, and in another example, the thin film etching rate on the substrate S can be improved during atomic layer etching. Further, as the gas adsorption rate is improved, a material with a low adsorption factor, such as a 2D material, can be used as the substrate S.

In some embodiments, as shown in FIG. 6, during at least some sections of the process for processing the substrate S, the switch SW3 may be turned off and the switch SW4 may be turned on to ground the second shower head 35.

For example, during at least a portion of the processing process for the substrate S, in a state in which the remote plasma P1 is formed inside the reaction space A1, the switch SW3 may be turned off and the switch SW4 may be turned on to ground the second shower head 35.

In another example, during at least a portion of the processing process for the substrate S, in a state in which the remote plasma P1 is not formed inside the reaction space A1, the switch SW3 may be turned off and the switch SW4 may be turned on to ground the second shower head 35.

In some embodiments, a process of depositing a thin film on the substrate S by atomic layer deposition (ALD) using the substrate processing apparatus 100a will be exemplarily described.

In order to form a thin film on the substrate S using the atom layer deposition (ALD) method, a precursor or a reaction gas may be supplied to the substrate S through the gas supply device 30. In some embodiments, during atomic layer deposition, a bias voltage may be applied to the second shower head 35 through the bias power supply unit 52 when a precursor or a source gas is supplied, a bias voltage may not be applied to the second shower head 35 when a reaction gas is supplied, and the second shower head 35 may be grounded, for example. Accordingly, the adsorption rate of the precursor or source gas on the substrate S may be increased, thereby increasing the thin film deposition rate.

In the substrate processing apparatuses 100 and 100a) described above, a bias voltage is applied to the susceptor 20 or the second shower head 35 as needed, and thus when the substrate S is processed, the gas adhesion efficiency can be increased, thereby increasing the processing rate and increasing productivity. In addition, according to the substrate processing apparatuses 100 and 100a described above, when semiconductor devices or display devices are manufactured, the thin film deposition rate can be increased, and when a thin film is deposited using atomic layer deposition (ALD) in patterns with a high aspect ratio, step coverage control, gap fill characteristic control, and thin film quality control in the patterns can be made possible.

It should be understood that the present disclosure has been described with reference to the embodiments illustrated in the drawings, but these are merely illustrative and various modifications and other equivalent embodiments can be made by those having ordinary knowledge in the art from the embodiments. Therefore, the true technical scope of the present disclosure should be determined by the technical idea of the appended claims.

What is claimed is:

1. An apparatus for processing a substrate comprising:
a chamber including a processing space in which the substrate is accommodatable and processible;
a susceptor coupled to the chamber to support the substrate in the processing space;
a gas supply device that is installed in a upper portion of the chamber and supplies a gas toward the susceptor;
an RF power device configured to supply RF power to at least a portion of the gas supply device in order to form remote plasma in a reaction space in the gas supply device; and
a bias power supply unit configured to selectively apply a bias voltage to another portion of the gas supply device or the susceptor.

2. The apparatus for processing a substrate according to claim 1, wherein the gas supply device includes:
a top plate having a gas inlet formed therein;
a first shower head that is disposed below the top plate and having first injection holes formed therein to inject a gas; and
a first insulating side wall interposed between the first shower head and the top plate to define the reaction space between the top plate and the first shower head, the RF power device is selectively connected to the top plate, and
the first shower head is grounded.

3. The apparatus for processing a substrate according to claim 2,
wherein the bias power supply unit is selectively connected to the susceptor.

4. The apparatus for processing a substrate according to claim 3,
wherein a precursor is supplied or a reaction gas is supplied to the substrate through the gas supply device in order to form a thin film on the substrate using an atomic layer deposition (ALD) method,
a bias voltage is applied to the susceptor through the bias power supply unit when the precursor is supplied, and
a bias voltage may not be applied to the susceptor and the susceptor is grounded when the reaction gas is supplied.

5. The apparatus for processing a substrate according to claim 1,
wherein the gas supply device further includes:
a second shower head that is disposed below the first shower head and has second injection holes formed therein to inject a gas; and
a second insulating side wall interposed between the first shower head and the second shower head to define a buffer space between the first shower head and the second shower head.

6. The apparatus for processing a substrate according to claim 5,
wherein the bias power supply unit is selectively connected to the second shower head.

7. The apparatus for processing a substrate according to claim 6,
wherein the susceptor is grounded.

8. The apparatus for processing a substrate according to claim 5,
wherein a precursor is supplied or a reaction gas is supplied to the substrate through the gas supply device in order to form a thin film on the substrate using an atomic layer deposition (ALD) method,
a bias voltage is applied to the second shower head through the bias power supply unit when the precursor is supplied, and
a bias voltage is not applied to the second shower head when the reaction gas is supplied.

9. The apparatus for processing a substrate according to claim 1,
wherein a bias voltage is selectively applied to another portion of the gas supply device or the susceptor when the remote plasma is formed in the reaction space.
